(19) United States
(12) Patent Application Publication
(10) Pub. No.: US 2025/0392267 A1
(43) Pub. Date: Dec. 25, 2025

(54) HIGH-FREQUENCY SWITCHING DEVICE

(71) Applicant: NRLAB Co., Ltd., Gyeonggi-do (KR)

(72) Inventors: Yoo Hwan KIM, Gyeonggi-do (KR); Chang Su WON, Gyeonggi-do (KR); Ye Seul SIM, Gyeonggi-do (KR); Seo Yeon CHOI, Gyeonggi-do (KR)

(21) Appl. No.: 19/238,906

(22) Filed: Jun. 16, 2025

(30) Foreign Application Priority Data
Jun. 21, 2024 (KR) 10-2024-0080865
May 22, 2025 (KR) 10-2025-0066868

(51) Int. Cl. H03F 1/52; H03F 3/24; H03K 17/56

(52) U.S. Cl. CPC H03F 1/52; H03K 17/56; H03F 3/245; H03F 2200/451

(57) ABSTRACT

Provided is a high-frequency switching device including: a switch configured to perform switching between a transmission mode and a reception mode for high-frequency radio signals; a power amplifier configured to supply power for driving the switch; and a switch controller configured to provide a switch voltage for operating the switch. The switch controller includes: a bias power generation unit; an overvoltage protection unit; an overcurrent protection unit; an MIPI protection unit; a mode detection unit configured to detect any one of the transmission mode or the reception mode for the high-frequency radio signals; and an adaptive voltage generation unit configured to selectively provides the switch voltage for switching operation of one of the transmission mode and the reception mode detected by the mode detection unit to the switch.

### CROSS-REFERENCE TO RELATED APPLICATION

This application claims priority to and the benefit of Korean Patent Application Nos. 10-2024-0080865 filed on Jun. 21, 2024 and 10-2025-0066868 filed on May 22, 2025, the disclosure of which is incorporated herein by reference in its entirety.

### FIELD

The present disclosure relates to a high-frequency switching device for improving Tx/Rx turn-on time.

### BACKGROUND

In a module configuration composed of a power amplifier, a low noise amplifier, an RF switch, and a controller IC that manages the power amplifier and the switch, the four ICs must collectively meet the overall system specifications to satisfy the Tx and Rx turn-on times when switching from low power mode to active mode.

The Tx turn-on time sequence refers to the point in time at which 90% of the Tx power is output from the antenna switch, following the transition of V_{IO} from OFF to ON or the application of the low power mode of MIPI (Mobile Industry Processor Interface) RFFE (RF Front-End Control Interface), the setting of registers required to turn on the Tx path, and the execution of an active trigger.

FIG. 1 is a reference diagram illustrating a signal transmission process between a conventional controller and a switch.

In conventional technology, the external Tx register is set in the controller, and when the active trigger occurs, the internal BGR of the controller operates, followed by the operations of the bias generator for the PA and the voltage generator for supplying power and generating bias to turn on the RF switch path. The Tx turn-on time is defined as the duration required for these operations to complete. Most of the time is spent on the operation of the voltage generator circuit for the bandgap and switch operations.

In addition to the positive voltage of the voltage generator, the RF switch also requires a negative voltage generator circuit, whose operating time must be considered. This negative voltage generator circuit is located inside the controller or the RF switch.

The Rx turn-on time refers to as a total time taken from the external setting of the register for LNA operation, to the activation of the RF switch for turning on a desired band path, including the time required for the voltage generator and the negative generator circuit to operate.

In modules where Tx and Rx ICs are integrated, OVP (Over Voltage Protection) and OCP (Over Current Protection) circuits are being added to protect the Tx power amplifier from external voltage and current.

### PRIOR ART DOCUMENT

Korean Patent No. 10-1823269

### SUMMARY

The present disclosure provides a high-frequency switching device that detects transmission (Tx) and reception (Rx) mode and applies different turn-on time sequences in Rx-only and Tx modes, thereby improving overall timing and reducing current consumption.

In one general aspect of the present disclosure, there is provided a high-frequency switching device including: a switch configured to perform switching between a transmission mode and a reception mode for high-frequency radio signals; a power amplifier configured to supply power for driving the switch; and a switch controller configured to provide a switch voltage for operating the switch. The switch controller includes: a bias power generation unit configured to supply bias power to the power amplifier; an overvoltage protection unit configured to protect the power amplifier from an external overvoltage; an overcurrent protection unit configured to protect the power amplifier from an external overcurrent; an MIPI protection unit configured to prevent MIPI errors; a mode detection unit configured to detect any one of the transmission mode or the reception mode for the high-frequency radio signals; and an adaptive voltage generation unit configured to selectively provides the switch voltage for switching operation of one of the transmission mode and the reception mode detected by the mode detection unit to the switch.

The mode detection unit may detect the transmission mode and the reception mode based on an operation status of at least one of the overvoltage protection unit, the overcurrent protection unit, and the MIPI protection unit upon execution of an active mode trigger.

Based on a detection result of the mode detection unit, the adaptive voltage generation unit may first output an external voltage to the switch in a bypass mode, and then generate a bias voltage for enabling normal operation of the switch in the transmission mode and output the bias voltage to the switch.

### BRIEF DESCRIPTION OF THE DRAWINGS

FIG. 1 is a reference diagram illustrating a signal transmission process between a conventional controller and a switch.

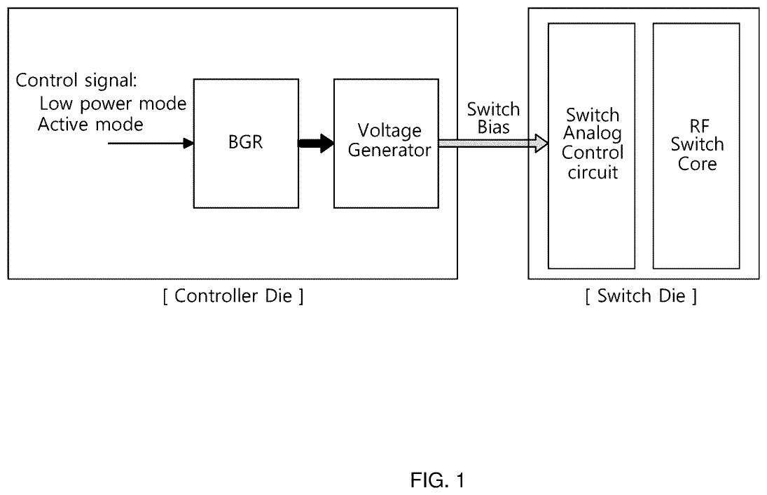

FIG. 2 is a block diagram illustrating a high-frequency switching device according to the present disclosure.

FIG. 3 is a reference diagram illustrating the Tx turn-on time and Rx turn-on time sequence according to the high-frequency switching device of the present disclosure.

FIG. 4 is a reference diagram for comparing the Tx turn-on time sequences between the present disclosure and the prior art.

### DETAILED DESCRIPTION

Hereinafter, preferred embodiments of the present disclosure will be described in detail with reference to the attached drawings.

The embodiments of the present disclosure are provided to give a more complete understanding of the present disclosure to those skilled in the art. These embodiments may be modified in various forms, and the scope of the present disclosure is not limited to the embodiments set forth herein. Rather, these embodiments are provided to ensure a more thorough and complete understanding of the present disclosure and to fully convey the spirit of the present disclosure to those skilled in the art.

The terminology used herein is for the purpose of describing particular embodiments only and is not intended to limit the present disclosure. As used herein, the singular form may include the plural form unless the context clearly indicates otherwise. As used herein, the term “and/or” includes any and all combinations of one or more of the listed items.

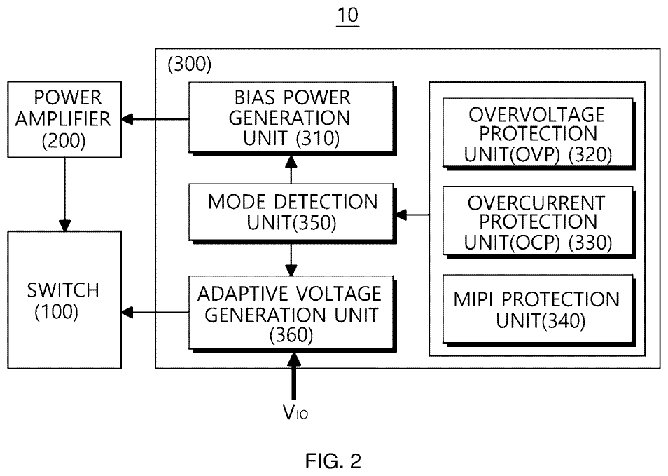

FIG. 2 is a block diagram illustrating a high-frequency switching device 10 according to the present disclosure.

The high-frequency switching device 10 is configured to detect Tx and Rx turn-on events to vary the output of the switch bias. Specifically, at the Tx turn-on event, the output voltage of the switch bias is adjusted depending on the normalization state of the OVP, OCP, and MIPI protection circuits inside the controller IC.

The high-frequency switching device 10 for this purpose includes a switch 100, a power amplifier 200, and a switch controller 300.

The switch 100 is configured to perform switching between a transmission (Tx) mode and a reception (Rx) mode for high-frequency radio signals. The switch 100 performs switching between a transmitter and a receiver. The switch 100 is an electrical on-off switch. When turned on, the switch 100 allows an input RF signal to be quickly transmitted to an output terminal with low loss. When turned off, the switch 100 ensures that a normal RF signal is transmitted to the output terminal without interference caused by the off state of the switch 100. In addition, the switch 100 must have good harmonics and IMD characteristics so as not to deteriorate linearity in large RF signals, and there must be no permanent destruction phenomenon due to large signals.

The power amplifier 200 is configured to supply power to the switch 100 for driving the switch 100. To this end, the power amplifier 200 is electrically connected to the switch 100.

The power amplifier 200 receives a small RF signal from the transceiver and amplifies the signal to enable smooth communication between a device and a base station. To this end, the power amplifier 200 is required to have high amplification efficiency, wide bandwidth, and high linearity.

The switch controller 300 is configured to provide a switching voltage to the switch 100 for the switch 100 to perform a switching operation.

To this end, the switch controller 300 includes a bias power generation unit 310, an overvoltage protection unit 320, an overcurrent protection unit 330, a MIPI protection unit 340, a mode detection unit 350, and an adaptive voltage generation unit 360.

The bias power generation unit 310 is configured to supply bias power to the power amplifier 200 for the operation of the power amplifier 200. To this end, the bias power generation unit 310 is electrically connected to the power amplifier 200.

The overvoltage protection unit 320 performs a function to protect the power amplifier 200 from an external overvoltage. The overvoltage protection unit 320 is configured to prevent permanent damage to the internal power amplifier 200 and communication failure that may occur when external power (e.g., VBAT or PMIC output) is supplied at a voltage different from an intended value. When an input voltage exceeds a predetermined level, the bias of the power amplifier 200 is turned off to prevent permanent damage.

The overcurrent protection unit 330 is configured to protect the power amplifier 200 from an external overcurrent. The overcurrent protection unit 330 is a circuit configured to prevent communication failure resulting from permanent damage to the IC caused by an overcurrent when the internal power amplifier 200 generates a current exceeding an intended value due to abnormal operating conditions.

The MIPI protection unit 340 is configured to prevent MIPI errors.

The MIPI protection unit 340 is a circuit configured to receive Tx/Rx mode and frequency band information from the transceiver via SCLK and SDATA, and to prevent permanent damage to the internal IC that may result from the reception of incorrect information for certain reason.

The mode detection unit 350 is configured to detect either a Tx mode or an Rx mode for high-frequency radio signals.

The mode detection unit 350 detects a Tx mode and an Rx mode based on an operation status of the overvoltage protection unit 320, the overcurrent protection unit 330, or the MIPI protection unit 340 upon execution of an active mode trigger.

For example, the mode detection unit 350 may detect the Tx mode when the overvoltage protection unit 320, the overcurrent protection unit 330, or the MIPI protection unit 340 is in an on state, and may detect the Rx mode when the MIPI protection unit 340 or the internal PA_Enable signal is in an off state.

The adaptive voltage generation unit 360 is configured to selectively provide a switching voltage to the switch 100 according to the detection signal of the mode detection unit 350. That is, the adaptive voltage generation unit 360 selectively provides a switching voltage to the switch 100 for a switching operation corresponding to either a Tx mode or an Rx mode detected by the mode detection unit 350.

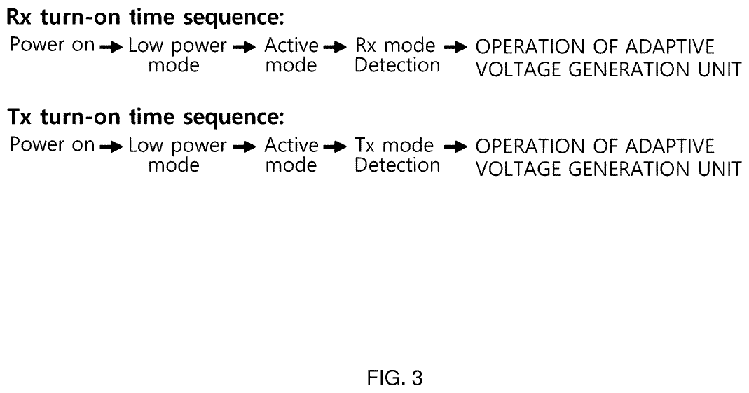

FIG. 3 is a reference diagram illustrating the Tx turn-on time and Rx turn-on time sequences according to the high-frequency switching device 10 of the present disclosure.

Referring to FIG. 3, the operation of the adaptive voltage generation unit 360 in response to Rx mode or Tx mode detection by the mode detection unit 350 during the Tx and Rx turn-on time sequences is illustrated.

When the mode detection unit 350 detects the Rx mode for high-frequency radio signals, power consumption in the bandgap reference (BGR circuit) (not shown) and the bias power generation unit 310, which is required for operation of the adaptive voltage generation unit 360 in the transmission mode (Tx mode), may be prevented and the operation timing of the BGR circuit and the adaptive voltage generation unit 360 may be improved.

That is, when operating in the Rx turn-on time sequence in FIG. 3, the mode detection unit 350 detects the Rx mode for high-frequency radio signals when the MIPI protection unit 340 or the internal PA_Enable signal is in an off state.

When the mode detection unit 350 detects the Rx mode, the bias power generation unit 310 and the BGR circuit are maintained in a disabled state, thereby preventing power from being consumed in the BGR circuit and the bias power generation unit 310.

At this time, in the Rx mode, the adaptive voltage generation unit 360 is bypassed by an externally applied voltage (V_{IO}). Accordingly, the adaptive voltage generation unit 360 immediately provides the externally applied voltage (V_{IO}) to the switch 100, thereby minimizing the time required to generate the voltage for the Rx mode switching of the switch 100.

This provides a significant advantage over the conventional technology, where the turn-on time is prolonged and unnecessary current is consumed because the BGR circuit and the bias power generation unit 310 remain active even in the Rx mode.

Meanwhile, in the Tx turn-on time sequence, the BGR circuit operates upon execution of an active mode trigger, and the overvoltage protection unit 320, the overcurrent protection unit 330, and the MIPI protection unit 340 operate.

The mode detection unit 350 detects the Tx mode for high-frequency radio signals when the overvoltage protection unit 320, the overcurrent protection unit 330, or the MIPI protection unit 340 is turned on upon execution of an active mode trigger.

When the mode detection unit 350 detects the Tx mode, the adaptive voltage generation unit 360 generates the voltage required for the Tx mode, which involves current consumption and delay caused by the operation of the BGR circuit.

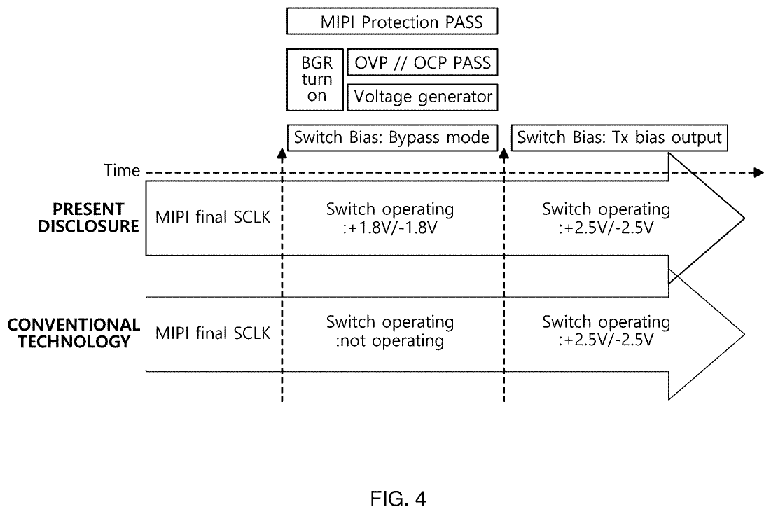

FIG. 4 is a reference diagram for comparing the Tx turn-on time sequences between the present disclosure and the prior art.

When the mode detection unit 350 detects the Tx mode, the BGR circuit is activated to provide the bandgap reference required for voltage generation in the adaptive voltage generation unit 360.

At this time, the adaptive voltage generation unit 360 of the present disclosure first outputs an external voltage (V_{IO}, e.g., 1.8 [V] to −1.8 [V]) to the switch 100 in bypass mode according to the Tx mode detection result, so that the operation of the negative generator can proceed in parallel with the operation of the BGR circuit.

Then, the adaptive voltage generation unit 360 switches from the bypass mode to the transmission output mode, thereby generating a bias voltage (e.g., 2.5 [V] to −2.5 [V]) that allows the switch 100 to operate normally in the Tx mode. In conventional technology, even after switching to the Tx mode, there is a waiting time during which the switch 100 does not operate. However, according to the present disclosure, when the Tx mode is detected, the adaptive voltage generation unit 360 immediately outputs an external voltage to the switch 100 in bypass mode, thereby reducing the Tx turn-on time of the switch 100.

According to the present disclosure, a protection circuit for a power amplifier or the like is included, and one of a transmission mode (Tx mode) or a reception mode (Rx mode) for a wireless signal is detected. A switching voltage corresponding to the detected mode is selectively provided to the switch. As a result, power consumption and switching time may be minimized in the Rx mode, and the time required for switching to the Tx mode may be reduced.

While the present disclosure has been described with reference to the accompanying drawings, it is to be understood that this description is merely illustrative of embodiments and is not to be construed as limiting the scope of the present disclosure.

Accordingly, the present disclosure is not limited to the specific embodiments described above. Various modifications and variations may be made by those skilled in the art without departing from the spirit and scope of the present disclosure, which is defined by the following claims.

What is claimed is:

1. A high-frequency switching device comprising:
a switch configured to perform switching between a transmission mode and a reception mode for high-frequency radio signals;
a power amplifier configured to supply power for driving the switch; and
a switch controller configured to provide a switch voltage for operating the switch,
wherein the switch controller comprises:
a bias power generation unit configured to supply bias power to the power amplifier;
an overvoltage protection unit configured to protect the power amplifier from an external overvoltage;
an overcurrent protection unit configured to protect the power amplifier from an external overcurrent;
an MIPI protection unit configured to prevent MIPI errors;
a mode detection unit configured to detect any one of the transmission mode or the reception mode for the high-frequency radio signals; and
an adaptive voltage generation unit configured to selectively provide the switch voltage for switching operation of one of the transmission mode and the reception mode detected by the mode detection unit to the switch.

2. The high-frequency switching device of claim 1, wherein the mode detection unit detects the transmission mode and the reception mode based on an operation status of at least one of the overvoltage protection unit, the overcurrent protection unit, and the MIPI protection unit upon execution of an active mode trigger.

3. The high-frequency switching device of claim 1, wherein, based on a detection result of the mode detection unit, the adaptive voltage generator first outputs an external voltage to the switch in a bypass mode, and then generates a bias voltage for enabling normal operation of the switch in the transmission mode and outputs the generated bias voltage to the switch.
